(19) United States
(12) Patent Application Publication
(10) Pub. No.: US 2025/0132765 A1
(43) Pub. Date: Apr. 24, 2025

(54) PULSE WIDTH MODULATION CIRCUIT TO GENERATE A FEEDBACK CLOCK

(71) Applicant: Microchip Technology Incorporated, Chandler, AZ (US)

(72) Inventor: Keith Curtis, Queen Creek, AZ (US)

(73) Assignee: Microchip Technology Incorporated, Chandler, AZ (US)

(21) Appl. No.: 18/923,751

(22) Filed: Oct. 23, 2024

Related U.S. Application Data
(60) Provisional application No. 63/592,773, filed on Oct. 24, 2023.

(51) Int. Cl. H03L 7/099; H03K 5/156; H03L 7/093; H03L 7/18

(52) U.S. Cl. CPC H03L 7/099; H03K 5/1565; H03L 7/093; H03L 7/18

(57) ABSTRACT

A device may have a reference divider circuit to divide a reference clock, a phase-frequency detector circuit to detect a detected phase difference and a detected frequency difference based on the reference divider output and a feedback clock, a loop filter circuit to filter the detector output, a voltage controlled oscillator (VCO) control output pin coupled to the loop filter output, a VCO clock divider control output pin to select a divisor of an external clock divider circuit, a divided VCO clock input pin for coupling to an output of the external clock divider circuit, a pulse-width modulation (PWM) circuit having a PWM clock input coupled to the divided VCO clock input pin, a period register to store a period value, a duty cycle register to store a duty cycle value and a pulse-width modulated output based on the period value and the duty cycle value.

### PRIORITY

This application claims priority to commonly owned U.S. Patent Application No. 63/592,773 filed Oct. 24, 2023, the entire contents of which are hereby incorporated by reference for all purposes.

### FIELD OF THE INVENTION

The present disclosure relates to phase lock circuits, including but not limited to phase-locked loops (PLLs) implemented with core independent peripherals.

### BACKGROUND

In electronic systems, a phase lock circuit may be used to generate a clock source. The phase lock circuit may be a phase-locked loop (PLL). The PLL may comprise a phase detector, a loop filter, and a controllable oscillator circuit (e.g., voltage controlled oscillator (VCO)). The PLL may receive an input from a reference signal and may generate an output at the output of the controllable oscillator circuit.

Generation of phase-coherent clock sources using a PLL requires external devices for PLL counter control circuits, loop filters, dual modulus prescalers, and VCOs. Control of these external devices requires an external control bus, including but not limited to a Serial Peripheral Interface (SPI) or an Inter-Integrated Circuit (I2C) bus. Additionally, these external devices increase the cost and complexity of the solution.

A PLL may be part of a microcontroller or may be a stand-alone device. A microcontroller generally comprises a central processing unit (CPU), program and data storage memory, input-output (I/O) ports, and a plurality of peripherals fabricated on an integrated circuit (IC) die (“chip”).

External as well as internal peripherals, including but not limited to PLLs, may handle their tasks with little or no code execution by, or supervision from, a CPU to maintain operation of the peripheral. Such peripherals may be termed Core Independent Peripherals (CIPs). As a result, CIPs simplify the implementation of complex control systems and give designers the flexibility to innovate. CIPs are internally integrated and may receive inputs from internal and external sources and may provide outputs to internal and external targets, such as other integrated peripherals or external components.

A PLL-generated clock source, whether part of a microcontroller or a stand-alone device, may take many cycles to lock onto the desired phase/frequency when stepping from one frequency to another.

There is a need for a CIP PLL device which requires limited external devices. There is also a need for a PLL device which reduces the number of cycles needed to lock onto the desired phase/frequency following a step from one frequency to another.

### SUMMARY

The examples herein enable a CIP PLL device which requires limited external devices and that reduce the number of cycles needed to lock onto the desired phase/frequency following a step from one frequency to another.

According to one example, a system is provided that includes a reference divider circuit to divide a reference clock, the reference divider circuit comprising a reference divider output. The system may include a phase-frequency detector circuit to detect a detected phase difference and a detected frequency difference based on the reference divider output and a feedback clock, the phase-frequency detector circuit comprising a divided reference clock input coupled to the reference divider output, a feedback clock input coupled to the feedback clock, and a detector output based on the detected phase and the detected frequency difference. The system may additionally include a loop filter circuit to filter the detector output, the loop filter circuit comprising a loop filter output. The system may also include a voltage controlled oscillator (VCO) circuit to generate a VCO clock output, the voltage controlled oscillator circuit comprising a VCO input coupled to the loop filter output, the VCO input to adjust at least one of a frequency and a phase of the VCO clock output. The system may include a divider circuit to divide the VCO clock output, the divider circuit comprising a divider clock input coupled to the VCO clock output, a divider control input, and a divider clock output. The system may include a pulse-width modulation (PWM) circuit, the pulse-width modulation circuit may comprise a PWM clock input coupled to the divider clock output; a period register to store a period value; a duty cycle register to store a duty cycle value; a pulse-width modulated output based on the period value and the duty cycle value, the pulse-width modulated output coupled to the divider control input; and a counter rollover output to generate the feedback clock.

Another example provides a device having a reference divider circuit to divide a reference clock, the reference divider circuit comprising a reference divider output. The device may include a phase-frequency detector circuit to detect a detected phase difference and a detected frequency difference based on the reference divider output and a feedback clock, the phase-frequency detector circuit may comprise a divided reference clock input coupled to the reference divider output, a feedback clock input coupled to the feedback clock, and a detector output based on the detected phase difference and the detected frequency difference. The device may additionally include a loop filter circuit to filter the detector output, the loop filter circuit comprising a loop filter output. The device may include a voltage controlled oscillator (VCO) control output pin coupled to the loop filter output, the VCO control output pin to adjust one of a frequency and a phase of a VCO clock output of an external voltage controlled oscillator circuit. The device may include a VCO clock divider control output pin to select a divisor of an external clock divider circuit. The device may include a divided VCO clock input pin for coupling to an output of the external clock divider circuit. The device may include a pulse-width modulation (PWM) circuit, the pulse-width modulation circuit may have a PWM clock input coupled to the divided VCO clock input pin; a period register to store a period value; a duty cycle register to store a duty cycle value; a pulse-width modulated output based on the period value and the duty cycle value, the pulse-width modulated output coupled to the VCO clock divider control output pin; and a counter rollover output to generate the feedback clock.

Another example provides the above-described device with an external clock divider circuit implemented as a dual modulus prescaler circuit external to the device. The dual modulus prescaler circuit may include a prescaler output coupled to the divided VCO clock input pin of the device, a prescaler control input coupled to the VCO clock divider control output pin of the device, and a prescaler clock input. The example additionally provides an external voltage controlled oscillator circuit that may be external to the device. The external voltage controlled oscillator circuit may include an oscillator input coupled to the VCO control output pin of the device, and an oscillator output coupled to the prescaler clock input.

Another example provides a method which may include dividing a reference clock, detecting a phase and frequency relationship between the divided reference clock and a feedback clock in a detector circuit, filtering a detector output of the detector circuit in a loop filter circuit, adjusting the phase or frequency of a voltage controlled oscillator based on a loop filter output of the loop filter circuit, dividing an output oscillation signal of the voltage controlled oscillator in a dual modulus prescaler circuit, clocking a pulse-width modulation circuit with a divided signal output of the dual modulus prescaler circuit, selecting a divisor used by the dual modulus prescaler circuit based on an output signal of the pulse-width modulation circuit, and generating the feedback clock based on a counter in the pulse-width modulation circuit.

### BRIEF DESCRIPTION OF THE DRAWINGS

The figures illustrate examples of CIP PLL devices.

FIG. 1 illustrates one of various examples of a CIP PLL device.

FIG. 2 illustrates two of various examples of a phase-frequency detector circuit implemented in one or more configurable logic cell peripherals of a microcontroller.

FIG. 3 illustrates one of various examples of a phase-frequency detector circuit and a loop filter circuit.

FIG. 4 illustrates one of various examples of a dual modulus prescaler circuit.

FIG. 5 illustrates one of various examples of a CIP PLL device.

FIG. 6 illustrates one of various examples of a CIP PLL device.

FIG. 7 illustrates one of various examples of a CIP PLL device.

FIG. 8 illustrates one of various examples of a CIP PLL device.

FIG. 9 illustrates a flow chart of an example method for using pulse-width modulation to generate a feedback clock in a phased lock loop.

FIG. 10 illustrates a flow chart of an example method for using pulse-width modulation to generate a feedback clock in a phased lock loop.

FIG. 11 illustrates a flow chart of an example method for using pulse-width modulation to generate a feedback clock in a phased lock loop.

FIG. 12 illustrates a flow chart of an example method for using pulse-width modulation to generate a feedback clock in a phased lock loop.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DETAILED DESCRIPTION

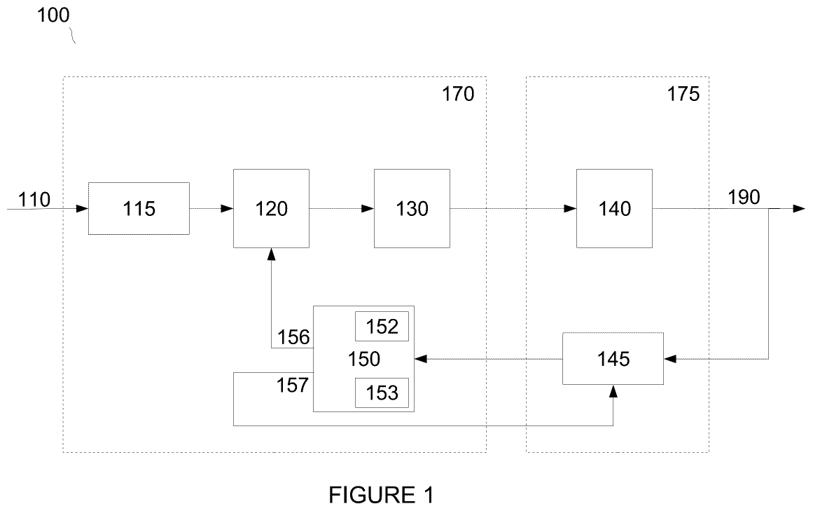

FIG. 1 illustrates one of various examples of a CIP PLL device 100. A reference clock 110 may be input to a reference divider circuit 115. In one of various examples, reference divider circuit 115 may divide reference clock 110 by an integer value. The integer value may be stored in a register and may be programmed by software or by hardware. In other examples, reference divider circuit 115 may divide reference clock 110 by a fractional value. The fractional value may be stored in a register and may be programmed by software or by hardware.

Phase-frequency detector circuit 120 may detect a phase and frequency relationship between the output of reference divider circuit 115 and an output of pulse-width modulation circuit 150. In one of various examples, phase-frequency detector circuit 120 may be implemented as one or more configurable logic cells. For example, the phase-frequency detector circuit 120 may be implemented in a CLC peripheral available on various Microchip PIC microcontrollers. In other examples, phase-frequency detector circuit 120 may be implemented as one or more clocked storage circuits, including but not limited to D-type flip-flops.

The output of phase-frequency detector circuit 120 may be input to loop filter circuit 130. Loop filter circuit 130 may be implemented as an active circuit, including one or more operational amplifiers. Loop filter circuit 130 may be implemented as a passive circuit, including one or more capacitors, resistors and inductors to generate a desired filter response.

The output of loop filter circuit 130 may input to voltage controlled oscillator (VCO) circuit 140. The output of loop filter circuit 130 may modify the frequency of the output of VCO circuit 140. The output of VCO circuit 140 may be PLL output 190. VCO circuit 140 may be part of external circuit 175.

PLL output 190 may be input to divider circuit 145. Divider circuit 145 may be a dual modulus prescaler divider or may be another type of divider circuit.

The output of divider circuit 145 may be the clock input to pulse-width modulation circuit 150. In one of various examples, pulse-width modulation circuit 150 may include a PWM generator to generate a PWM signal based on the output of divider circuit 145.

A first output 156 of pulse-width modulation circuit 150 may be input to phase-frequency detector circuit 120. First output 156 may represent the period of the PWM signal generated by pulse-width modulation circuit 150. In an example, the period of the PWM signal may correspond to period register 152 of pulse-width modulation circuit 150 and may be set by software running on a microcontroller comprising pulse-width modulation circuit 150. In an example, first output 156 may be a counter rollover output and may be generated based on a period counter rollover within pulse-width modulation circuit 150. According to this example, pulse-width modulation circuit 150 may have a period counter that may measure the time for the complete pulse-width modulation cycle (e.g., corresponding to period register 152). In an example, a 1 KHz pulse-width modulation with a 25% duty cycle may have a period counter that measures the 1 KHz (1 ms) period. The pulse-width modulation circuit 150 may have a comparator circuit that may set first output 156 (counter rollover output) when the period counter rolls over from max count (e.g., corresponding to period register 152) to zero. The comparator circuit may clear first output 156 when the period counter reaches a value corresponding to a 50% duty cycle. First output 156 may also be termed a feedback clock.

A second output 157 of pulse-width modulation circuit 150 may be input to divider circuit 145. Second output 157 may represent the PWM output signal generated by pulse-width modulation circuit 150. In an example, second output 157 may be based on registers in pulse-width modulation circuit 150 that store a period value (e.g., period register 152) and a duty cycle value (e.g., duty cycle register 153). These registers may be set by software running on a microcontroller comprising pulse-width modulation circuit 150. According to an example, pulse-width modulation circuit 150 may have a period counter that may measure the time for the complete pulse-width modulation cycle (e.g., corresponding to period register 152). In an example, a 1 KHz pulse-width modulation with a 25% duty cycle may have a period counter that measures the 1 KHz (1 ms) period. The pulse-width modulation circuit 150 may have a comparator circuit that may set second output 157 when the period counter rolls over from max count (e.g., corresponding to period register 152) to zero. The comparator circuit may clear second output 157 when the period counter reaches a value corresponding to a 25% duty cycle.

In operation, phase-frequency detector circuit 120 may detect a difference in phase and frequency between the output of reference divider circuit 115 and first output 156 of pulse-width modulation circuit 150. The output of phase-frequency detector circuit 120 may be filtered by loop filter circuit 130 and may control VCO 140 to produce a stable output at PLL output 190. The frequency of PLL output 190 may be changed by changing one or more of the period value in period register 152 of pulse-width modulation circuit 150 and the duty cycle value in duty cycle register 153 of pulse-width modulation circuit 150.

Reference divider circuit 115, phase-frequency detector circuit 120, loop filter circuit 130, and pulse-width modulation circuit 150 may be peripheral device 170. In an example, peripheral device 170 may include other components. In the same or different examples, peripheral device 170 may comprise multiple peripherals, respective peripherals corresponding to reference divider circuit 115, phase-frequency detector circuit 120, loop filter circuit 130, and pulse-width modulation circuit 150. In an example, peripheral device 170 may be part of a microcontroller and VCO 140 and divider circuit 145 may an external circuit 175 (i.e., external to a microcontroller). External circuit 175 may comprise a single component, or may comprise multiple components communicatively coupled as illustrated in FIG. 1.

A microcontroller may configure CIP PLL device 100 to operate as a core-independent peripheral. For example, a microcontroller may initialize reference divider circuit 115, phase-frequency detector circuit 120, loop filter circuit 130, and pulse-width modulation circuit 150, and these circuits may thereafter operate with little or no intervention by the microcontroller. In another example, reference divider circuit 115, phase-frequency detector circuit 120, loop filter circuit 130, and pulse-width modulation circuit 150 may be configured to operate out of reset without any intervention by a microcontroller.

Although FIG. 1 illustrates various components of CIP PLL device 100, other example devices may include more or fewer components. In additional examples, specific components of CIP PLL device 100 may include features in addition to those described above or may omit some of the features described above.

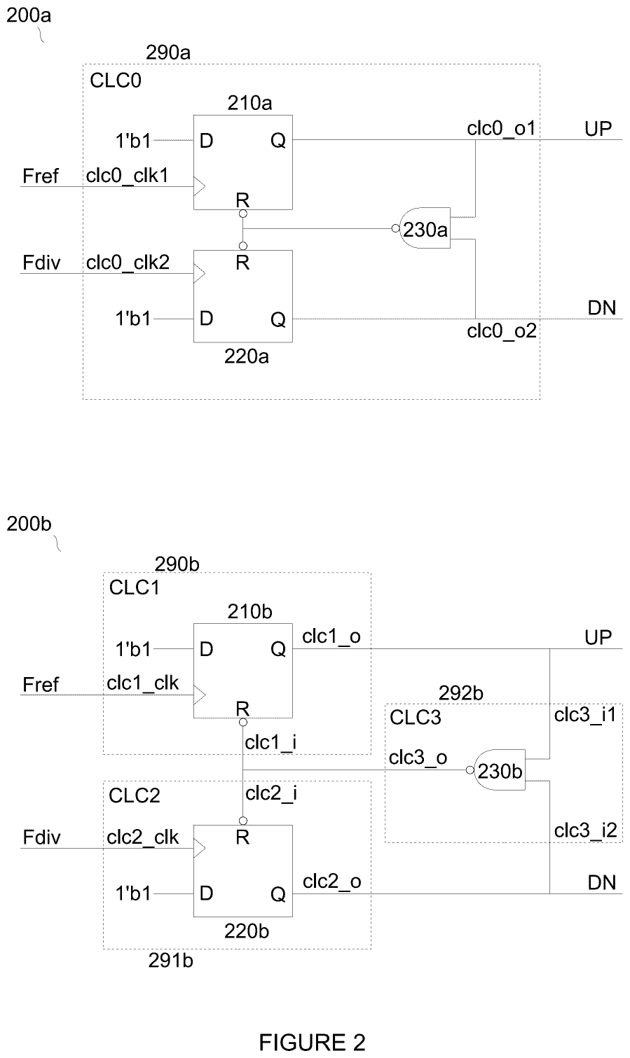

FIG. 2 illustrates two of various examples of a phase-frequency detector circuit implemented in one or more configurable logic cell peripherals of a microcontroller. A configurable logic cell peripheral (CLC) may provide programmable logic that operates outside the speed limitations of software execution. A CLC may take a number of input signals and, through the use of configurable gates, may reduce the input signals into logic lines that may drive selectable single-output logic functions. In an example, input sources to a CLC may be one or more of the following: I/O pins of a microcontroller, internal clocks of a microcontroller, peripheral outputs, register bits. The CLC output may be directed internally to one or more peripherals and output pins of the microcontroller. A CLC may be configured to include combinatorial logic (e.g., AND, NAND, AND-OR, AND-OR-INVERT, OR-XOR, OR-XNOR, without limitation) and latches (e.g., S-R, clocked D with Set and Reset, transparent D with Set and Reset, clocked J-K with Reset, without limitation) In an example, a CLC peripheral may be configured through software, for example, by writing configuration information to registers in the CLC peripheral. Once these registers are set up, the CLC may run independently of software control until the registers are changed via software.

In an example, phase-frequency detector circuit 200a may be implemented in CLC0 290a. CLC0 290a may be configured with two clock input pins, clc0_clk1 and clc0_clk2, coupled to a reference frequency (Fref) and a divided clock frequency (Fdiv), respectively. CLC0 290a may be configured to use upcounter flip-flop 210a, which may be configured to have a D-input coupled to a logic one value (1′b1). Upcounter flip-flop 210a may be configured to have a clock input coupled to reference clock Fref via the clc0_clk1 input. In one of various examples, reference clock Fref may be the output of reference divider circuit 115 as described and illustrated in reference to FIG. 1. CLC0 290a may be configured to use NAND gate 230a. Upcounter flip-flop 210a may be configured to have an inverted reset input coupled to the output of NAND gate 230a. The output of upcounter flip-flop 210a may be configured to be coupled to a first input of NAND gate 230a and to a clc0_o1 output of CLC0 290a.

CLC0 290a may be configured to use downcounter flip-flop 220a, which may be configured to have a D-input coupled to a logic one value (1′b1). Downcounter flip-flop 220a may be configured to have a clock input coupled to divided clock frequency Fdiv via the clc0_clk2 input. In one of various examples, divided clock frequency Fdiv may be first output 156 of pulse-width modulation circuit 150 as described and illustrated in reference to FIG. 1. Downcounter flip-flop 220a may be configured to have an inverted reset input coupled to the output of NAND gate 230a. The output of downcounter flip-flop 220a may be configured to be coupled to a second input of NAND gate 230a and to a clc0_o2 output of CLC0 290a.

In operation, software running on a microcontroller comprising CLC0 290a may configure CLC0 290a as illustrated and described, for example, by writing configuration information to registers in CLC0 290a (not shown). Once these registers are set up, CLC0 290a may operate as phase-frequency detector circuit 200a independently of software control (or other intervention by the microcontroller). As configured, output clc0_o may operate as an error signal that indicates that the PLL output (e.g., PLL output 190 in FIG. 1) should be adjusted up (UP) and output clc0_o2 may operate as an error signal that indicates that the PLL output should be adjusted down (DN).

In a further example, phase-frequency detector circuit 200b may be implemented by three CLCs (CLC1 290b, CLC2 291b, and CLC3 292b) whereas phase-frequency detector circuit 200a may be implemented by a single CLC (CLC0 290a). In various other examples, implementing a phase-frequency detector circuit may utilize any number of CLCs. The particular implementation may correspond to the complexity of the CLCs that are available in a peripheral of a microcontroller.

CLC1 290b may be configured with clock input pin clc1_clk, input pin clc1_i, and output pin clc1_o. Clock input pin clc1_clk may be configured to be coupled to a reference frequency (Fref). CLC1 290b may be configured to use upcounter flip-flop 210b, which may may be configured to have a D-input coupled to a logic one value (1′b1). Upcounter flip-flop 210b may be configured to have a clock input coupled to reference clock Fref via the clc1_clk input. Upcounter flip-flop 210b may be configured to have an inverted reset input (R) coupled to input clc1_i. In one of various examples, reference clock Fref may be the output of reference divider circuit 115 as described and illustrated in reference to FIG. 1.

CLC2 291b may be configured with clock input pin clc2_clk, input pin clc2_i, and output pin clc2_o. Clock input pin clc2_clk may be configured to be coupled to a divided clock frequency (Fdiv). CLC2 291b may be configured to use downcounter flip-flop 220b, which may have a D-input coupled to a logic one value (1′b1). Downcounter flip-flop 220b may be configured to have a clock input coupled to divided clock frequency Fdiv via the clc2_clk input. Downcounter flip-flop 220b may be configured to have an inverted reset input (R) coupled to input clc2_i. In one of various examples, divided clock frequency Fdiv may be first output 156 of pulse-width modulation circuit 150 as described and illustrated in reference to FIG. 1.

CLC3 292b may be configured with input pin clc3_i1, input pin clc3_i2, and output pin clc3_o. Input pin clc3_i1 may be configured to be coupled to CLC1 290b output pin clc1_o. Input pin clc3_i2 may be configured to be coupled to CLC2 291b output pin clc2_o. Output pin clc3_o may be configured to be coupled to CLC1 290b input pin clc1_i and CLC2 291b input pin clc2_i.

In operation, software running on a microcontroller comprising CLC1 290b, CLC2 291b, and CLC3 292b may configure CLC1 290b, CLC2 291b, and CLC3 292b as illustrated and described, for example, by writing configuration information to registers in CLC1 290b, CLC2 291b, and CLC3 292b (not shown). Once these registers are set up, CLC1 290b, CLC2 291b, and CLC3 292b may operate as phase-frequency detector circuit 200b independently of software control (or other intervention by the microcontroller). As configured, CLC1 290b output clc1_o may be an error signal that indicates that the PLL output (e.g., PLL output 190 in FIG. 1) should be adjusted up (UP), and CLC2 291b output clc2_o may be an error signal that indicates that the PLL output should be adjusted down (DN).

Although FIG. 2 illustrates various components of a phase-frequency detector circuit implemented in one or more configurable logic cell peripherals of a microcontroller, other example devices may include more or fewer components. In additional examples, specific components of a phase-frequency detector circuit may include features in addition to those described above or may omit some of the features described above.

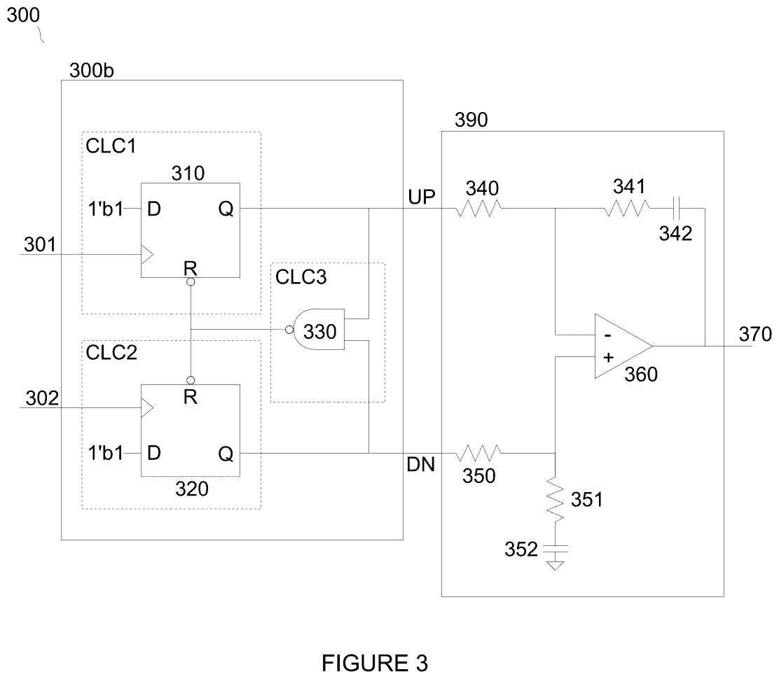

Element 300 in FIG. 3 illustrates one of various examples of phase-frequency detector circuit 300b and loop filter circuit 390. Phase-frequency detector circuit 300b and loop filter circuit 390 may represent one of various examples of phase-frequency detector circuit 120 and loop filter circuit 130 as described and illustrated in reference to FIG. 1. Phase-frequency detector circuit 300b corresponds to phase-frequency detector circuit 200b (FIG. 2), e.g., is implemented by three configurable logic cells, CLC1, CLC2, and CLC3. Upcounter flip-flop 310 corresponds to upcounter flip-flop 210b (FIG. 2), downcounter flip-flop 320 corresponds to downcounter flip-flop 220b (FIG. 2), and NAND gate 330 corresponds to NAND gate 230b (FIG. 2). Reference clock input 301 corresponds to reference clock frequency Fref (FIG. 2) and divided clock input 302 corresponds to divided clock frequency Fdiv (FIG. 2).

In one of various examples, the output of upcounter flip-flop 310 (UP) may be coupled to upcounter resistor 340. The output of downcounter flip-flop 320 (DN) may be coupled to downcounter resistor 350. Upcounter resistor 340 may be coupled to the inverting input of amplifier 360, and to feedback resistor 341. Feedback resistor 341 may be coupled to feedback capacitor 342. Feedback resistor 341 and feedback capacitor 342 may form a negative feedback loop from the output of amplifier 360 to the inverting input of amplifier 360. Downcounter resistor 350 may be coupled to the non-inverting input of amplifier 360, and to load resistor 351. Load resistor 351 may be coupled to load capacitor 352.

The output of amplifier 360 may be input to a voltage controlled oscillator. In one of various examples, the voltage controlled oscillator may be VCO circuit 140 as described and illustrated in reference to FIG. 1.

In operation, reference clock input 301 and divided clock input 302 may adjust output 370 of loop filter circuit 390 and control the output frequency of a voltage controlled oscillator.

Although FIG. 3 illustrates various components of a phase-frequency detector circuit and a loop filter circuit, other example devices may include more or fewer components. In additional examples, specific components of a phase-frequency detector circuit and a loop filter circuit may include features in addition to those described above or may omit some of the features described above.

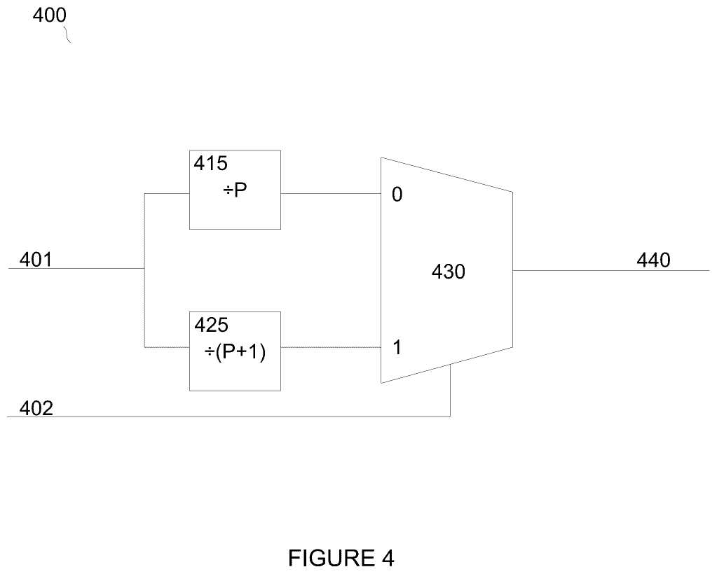

FIG. 4 illustrates one of various examples of a dual modulus prescaler circuit 400. Dual modulus prescaler circuit 400 may comprise clock input 401, control input 402, divide-by-P circuit 415, divide-by-P-plus-one circuit 425, and divided clock output 440. In one of various examples, the dual modulus prescaler circuit 400 may be divider circuit 145 as described and illustrated in reference to FIG. 1.

In operation, divide-by-P circuit 415 may divide clock input 401 by (P) and divide-by-P-plus-one circuit 425 may divide clock input 401 by (P+1), where P is an integer. Select gate 430 may select the output of either circuit 415 or 425 as divided clock output 440 based on control input 402.

Although FIG. 4 illustrates various components of a dual modulus prescaler circuit 400, other example devices may include more or fewer components. In additional examples, specific components of a dual modulus prescaler circuit may include features in addition to those described above or may omit some of the features described above.

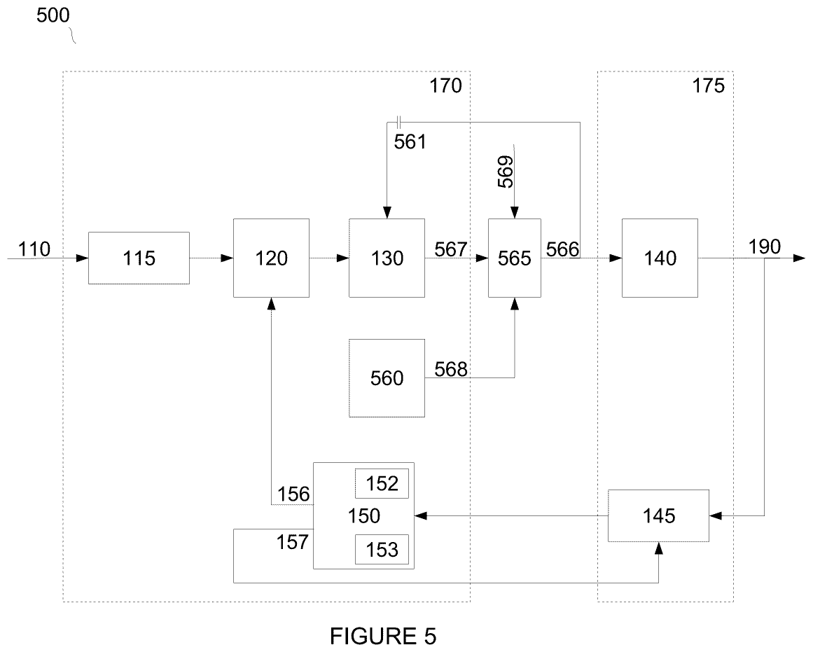

FIG. 5 illustrates one of various examples of a CIP PLL device 500. Elements 110, 115, 120, 130, 140, 145, 150, 152, 153, 156, 157, 170, 175, and 190 may correspond to the elements illustrated and described with respect to FIG. 1. In an example, CIP PLL device 500 may include digital-to-analog converter (DAC) 560. In the same or different examples, peripheral device 170 may be part of a microcontroller and may include DAC 560. DAC 560 may convert a digital value (e.g., a value stored in a register) and convert that value to an analog output.

CIP PLL device 500 may include selector circuit 565 having control input 569, DAC input 568, loop filter input 567, and VCO control output 566. DAC input 568 may be coupled to the output of DAC 560. Loop filter input 567 may be coupled to the output of loop filter circuit 130. Selector circuit may be a MUX or other digital or analog circuit that selects either DAC input 568 or loop filter input 567 as VCO control output 566 based on control input 569. In an example, control input 569 may be controlled by software (e.g., software running on a microcontroller writes to a control input configuration register (not illustrated)).

CIP PLL device 500 may include feedback capacitor 561 coupled to (1) VCO control output 566 of selector circuit 565 and (2) loop filter circuit 130.

In operation, control input 569 of selector circuit 565 may be configured to select loop filter input 567 as VCO control output 566 and may, thus, couple loop filter input 567 to VCO control output 566. When the clock frequency of PLL output 190 is changed (e.g., when one or more of period register 152 and duty cycle register 153 (or other PWM configuration value) is changed by software running on the microcontroller), it will take some time (e.g., a number of reference clock cycles) for CIP PLL device 500 to lock onto the new clock frequency when loop filter input 567 is selected as VCO control output 566. In an example, this lock time may be accelerated by (1) setting the DAC 560 output to a value corresponding to a VCO control value for the new frequency and (2) configuring control input 569 of selector circuit 565 to select DAC input 568 as VCO control output 566. In this configuration, DAC input 568 may be coupled to VCO control output 566. In an example, DAC 560 output may be controlled by software (e.g., software running on a microcontroller may write to a configuration register in DAC 560 (not illustrated)). DAC 560 output values corresponding to frequencies supported by CIP PLL device 500 may be determined based on the specific device/system (e.g., through testing performed during software development). While DAC input 568 is selected as VCO control output 566, DAC 560 output may charge feedback capacitor 561 to the new VCO control voltage. In an example, when feedback capacitor 561 is charged to the control voltage corresponding to the new frequency, control input 569 of selector circuit 565 may be configured to select loop filter input 567 as VCO control output 566 so that loop filter input 567 is re-coupled to VCO control output 566. Thus, in examples of CIP PLL device 500, temporarily selecting the DAC 560 output as the VCO control output 566 may accelerate the time it takes for the PLL to lock onto a new frequency.

Although FIG. 5 illustrates various components of a CIP PLL device 500, other example devices may include more or fewer components. In additional examples, specific components of a CIP PLL device may include features in addition to those described above or may omit some of the features described above.

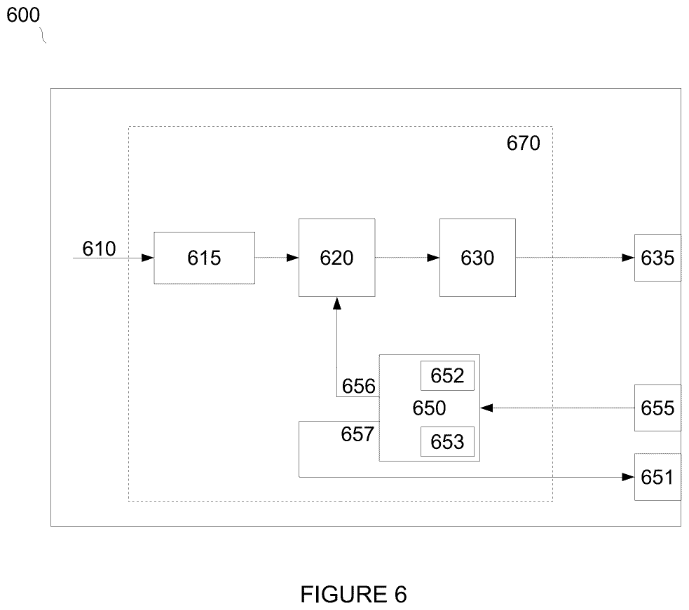

FIG. 6 illustrates one of various examples of a CIP PLL device 600. Elements 610, 615, 620, 630, 650, 652, 653, 656, 657, and 670 may correspond to similarly numbered elements illustrated and described with respect to FIG. 1 (i.e., 110, 115, 120, 130, 150, 152, 153, 156, 157, and 670, respectively). CIP PLL device 600 may comprise VCO control output pin 635, VCO clock divider control output pin 651, and divided VCO clock input pin 655. VCO control output pin 635 may be coupled to the output of loop filter circuit 630. VCO clock divider control output pin 651 may be coupled to output 657 of pulse-width modulation circuit 650. Divided VCO clock input pin 655 maybe coupled to the clock input to pulse-width modulation circuit 650. CIP PLL device 600 may be implemented as one or more peripherals 670 of a microcontroller. In an example, phase-frequency detector circuit 620 may be implemented by one or more CLCs (e.g., as illustrated in FIG. 2).

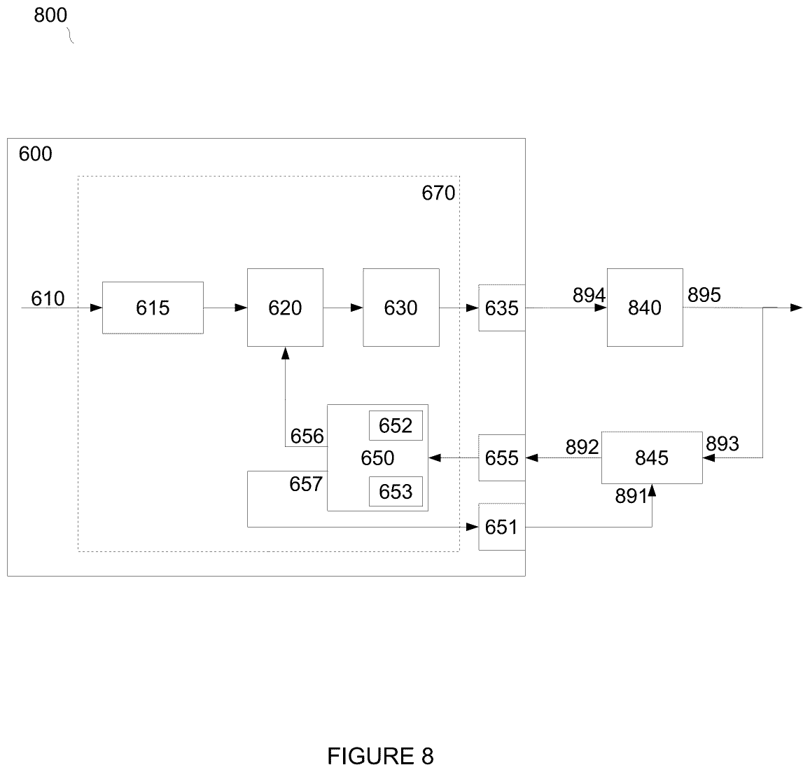

In operation, phase-frequency detector circuit 620 may detect a difference in phase and frequency between the output of reference divider circuit 615 and first output 656 of pulse-width modulation circuit 650 when CIP PLL device 600 is coupled with an external voltage controlled oscillator and divider circuit (e.g., FIG. 8). The output of phase-frequency detector circuit 620 may be filtered by loop filter circuit 630 and may provide a control voltage on VCO control output pin 635 for controlling an external voltage controlled oscillator. The frequency of an external voltage controlled oscillator may be changed by changing one or more of the period value in period register 652 of pulse-width modulation circuit 650 and the duty cycle value in duty cycle register 653 of pulse-width modulation circuit 650.

Although FIG. 6 illustrates various components of a CIP PLL device 600, other example devices may include more or fewer components. In additional examples, specific components of a CIP PLL device may include features in addition to those described above or may omit some of the features described above.

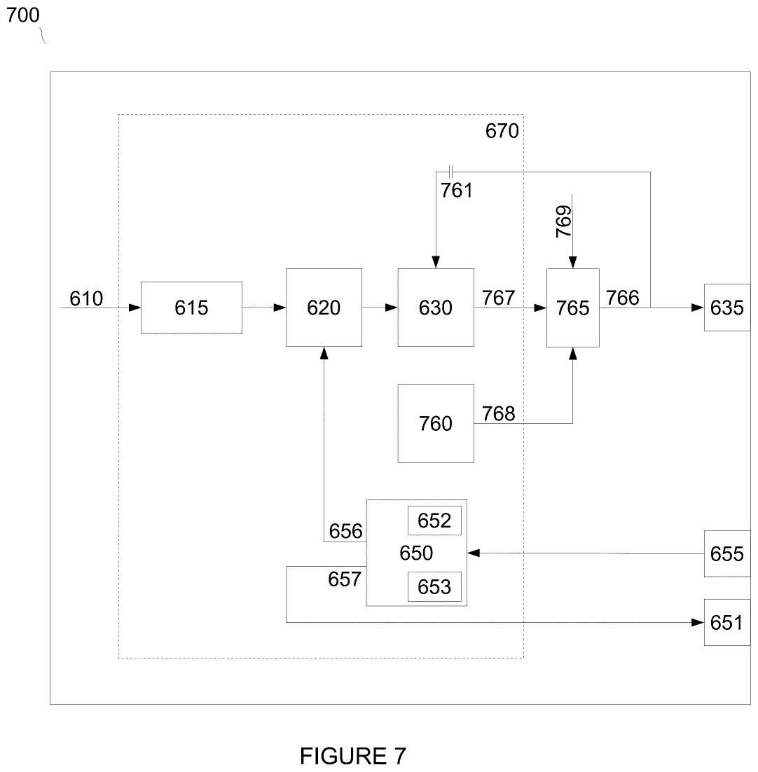

FIG. 7 illustrates one of various examples of a CIP PLL device 700. Elements 610, 615, 620, 630, 635, 650, 651, 652, 653, 655, 656, 657, and 670 may correspond to the same numbered elements illustrated and described with respect to FIG. 6. CIP PLL device 700 may include selector circuit 765 having control input 769, DAC input 768, loop filter input 767, and VCO control output 766. DAC input 768 may be coupled to the output of DAC 760. Loop filter input 767 may be coupled to the output of loop filter circuit 630. VCO control output 766 may be coupled to VCO control output pin 635. Selector circuit may be a MUX or other digital or analog circuit that selects either DAC input 768 or loop filter input 767 as VCO control output 766 based on control input 769. In an example, control input 769 may be controlled by software (e.g., software running on a microcontroller writes to a control input configuration register (not illustrated)). CIP PLL device 700 may include feedback capacitor 761 coupled to (1) VCO control output 766 of selector circuit 765 and (2) loop filter circuit 630.

The operation of CIP PLL device 700 is the same as described for CIP PLL device 500, where like-numbered elements operate similarly.

Although FIG. 7 illustrates various components of a CIP PLL device 700, other example devices may include more or fewer components. In additional examples, specific components of a CIP PLL device may include features in addition to those described above or may omit some of the features described above.

FIG. 8 illustrates one of various examples of a CIP PLL device 800. Elements 610, 615, 620, 630, 635, 650, 651, 652, 653, 655, 656, 657, and 670 may correspond to the same numbered elements illustrated and described with respect to CIP PLL device 600 in FIG. 6. CIP PLL device 800 may include a voltage controlled oscillator 840 having control input 894 and VCO output 895. CIP PLL device 800 may include clock divider circuit 845 having clock input 893 coupled to VCO output 895, control input 891 coupled to VCO clock divider control output pin 651, and output 892 coupled to divided VCO clock input pin 655. In an example, a microcontroller may include CIP PLL device 600, whereas voltage controlled oscillator 840 and clock divider circuit 845 may be external to the microcontroller. In the same or different examples, clock divider circuit 845 may be implemented as a dual modulus prescaler circuit.

The operation of CIP PLL device 800 is the same as described for CIP PLL device 600 and 100, where like-numbered elements operate similarly.

Although FIG. 8 illustrates various components of a CIP PLL device 800, other example devices may include more or fewer components. In additional examples, specific components of a CIP PLL device may include features in addition to those described above or may omit some of the features described above.

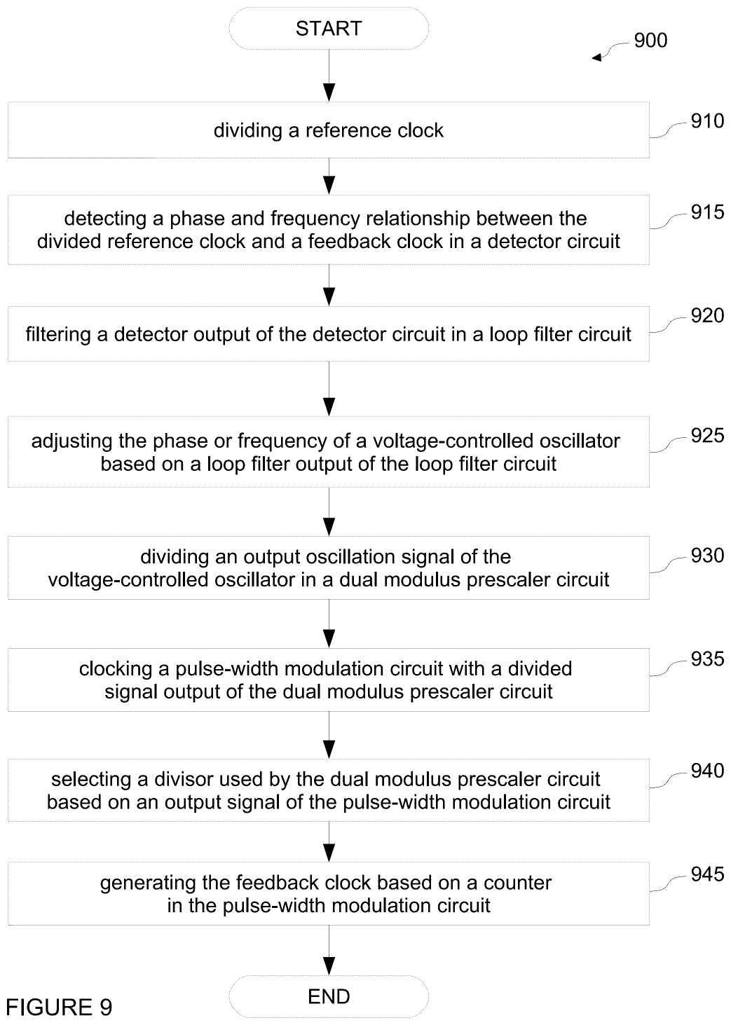

FIG. 9 illustrates a flow chart of an example method 900 for using pulse-width modulation to generate a feedback clock in a phased lock loop. According to one example, method 900 may begin at block 910. Teachings of the present disclosure may be implemented in a variety of configurations of CIP PLL device 100. As such, the initialization point for method 900 and the order of 910-945 comprising method 900 may depend on the implementation chosen.

At block 910, a reference clock may be divided. In an example, the reference clock may be divided by a circuit such as reference divider circuit 115 (FIG. 1). At block 915, the phase and frequency relationship between the divided reference clock and a feedback clock may be detected in a detector circuit. In example, the detection may be performed by phase-frequency detector circuit 120 (FIG. 1). In the same or different examples, a microcontroller may configure a configurable logic cell peripheral of the microcontroller to detect the phase and frequency relationship between the divided reference clock and the feedback clock (e.g., as depicted in 200a and 200b in FIG. 2). At block 920, a detector output of the detector circuit may be filtered in a loop filter circuit. In an example, the filtering may be performed by loop filter circuit 130 (FIG. 1). In the same or different example, a microcontroller may comprise the loop filter circuit, the loop filter circuit may comprise an operational amplifier, and the operational amplifier may be used to filter the detector output of the detector circuit.

At block 925, the phase or frequency of a voltage controlled oscillator may be adjusted based on the loop filter output of the loop filter. In an example, this adjustment may be for voltage controlled oscillator circuit 140 based on the output of loop filter circuit 130 (FIG. 1). At block 930, an output oscillation signal of the voltage controlled oscillator may be divided in a dual modulus prescaler circuit. In an example, output oscillation signal 190 may be divided in divider circuit 145 (FIG. 1), which may be a dual modulus prescaler circuit (e.g., FIG. 4). At block 935, a pulse-width modulation circuit may be clocked with a divided signal output of the dual modulus prescaler circuit. In an example, pulse-width modulation circuit 150 may be clocked with the divided signal of divider circuit 145 (FIG. 1), which may be a dual modulus prescaler circuit (e.g., FIG. 4). At block 940, a divisor used by the dual modulus prescaler circuit may be selected based on an output signal of the pulse-width modulation circuit. In an example, a divisor used by divider circuit 145 (FIG. 1), which may be a dual modulus prescaler circuit (e.g., FIG. 4), may be selected based on output signal 157 of pulse-width modulation circuit 150 (FIG. 1). At block 945, a feedback clock may be generated based on a counter in the pulse-width modulation circuit. In an example, feedback clock 156 may be generated based on a counter in pulse-width modulation circuit 150 (FIG. 1). In the same or different examples, the feedback clock may be generated based on the counter corresponding to a period setting in the pulse-width modulation circuit, for example, a setting of period register 152 in pulse-width modulation circuit 150 (FIG. 1).

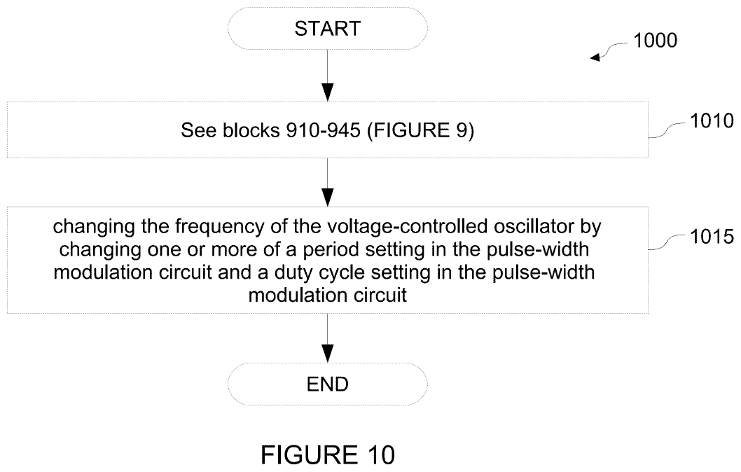

Although FIG. 9 discloses a particular number of operations related to method 900, method 900 may be executed with greater or fewer operations than those depicted in FIG. 9. For example, after block 945, method 900 may continue with additional operations illustrated in FIGS. 10-12. In addition, although FIG. 9 discloses a certain order of operations to be taken with respect to method 900, the operations comprising method 900 may be completed in any suitable order.

FIG. 10 illustrates a flow chart of an example method 1000 for using pulse-width modulation to generate a feedback clock in a phased lock loop. According to one example, method 1000 may begin at block 1010. Teachings of the present disclosure may be implemented in a variety of configurations of CIP PLL device 100. As such, the initialization point for method 1000 and the order of 1010-1045 comprising method 1000 may depend on the implementation chosen.

According to an example, block 1010 may be the same as blocks 910-945 in FIG. 9. At block 1015, the frequency of the voltage controlled oscillator may be changed by changing one or more of a period setting in the pulse-width modulation circuit and a duty cycle setting in the pulse-width modulation circuit. In an example, the frequency of voltage controlled oscillator circuit 140 may be changed by changing one or more of a period setting in period register 152 of pulse-width modulation circuit 150 and a duty cycle setting in duty cycle register 153 of pulse-width modulation circuit 150 (FIG. 1).

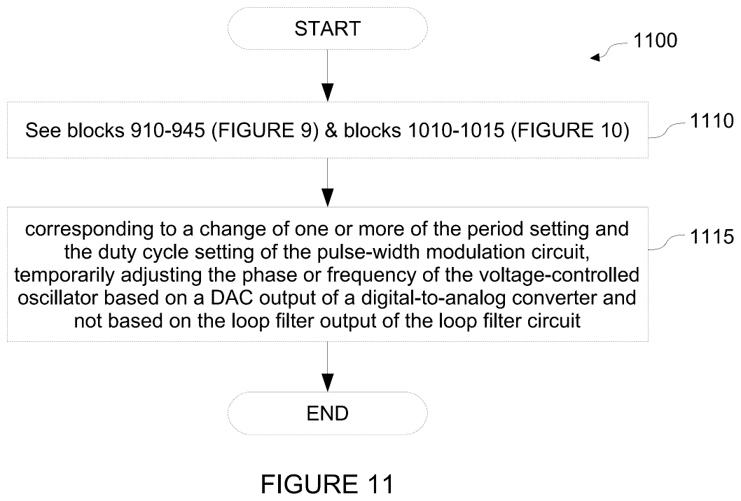

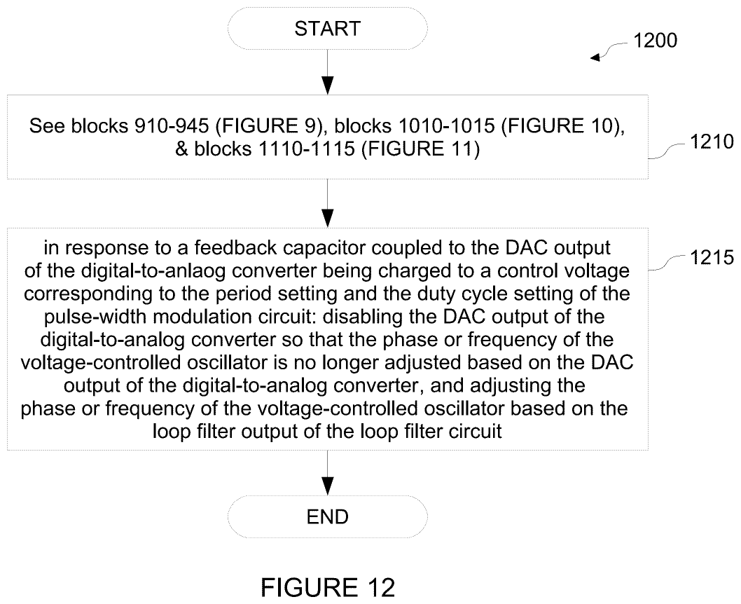

Although FIG. 10 discloses a particular number of operations related to method 1000, method 1000 may be executed with greater or fewer operations than those depicted in FIG. 10. For example, after block 1015, method 1000 may continue with additional operations illustrated in FIGS. 11-12. In addition, although FIG. 10 discloses a certain order of operations to be taken with respect to method 1000, the operations comprising method 1000 may be completed in any suitable order.

FIG. 11 illustrates a flow chart of an example method 1100 for using pulse-width modulation to generate a feedback clock in a phased lock loop. According to one example, method 1100 may begin at block 1110. Teachings of the present disclosure may be implemented in a variety of configurations of CIP PLL device 100. As such, the initialization point for method 1100 and the order of 1110-1115 comprising method 1100 may depend on the implementation chosen.

According to an example, block 1110 may be the same as blocks 910-945 in FIG. 9 and blocks 1010-1015 in FIG. 10. At block 1115, corresponding to a change of one or more of the period setting and the duty cycle setting of the pulse-width modulation circuit, the phase or frequency of the voltage controlled oscillator may be temporarily adjusted based on a DAC output of a digital-to-analog converter and not based on the loop filter output of the loop filter circuit. In an example, corresponding to a change of one or more of period setting in period register 152 and duty cycle setting in duty cycle register 153 of pulse-width modulation circuit 150, the phase or frequency of the voltage controlled oscillator circuit 140 may be temporarily adjusted based on DAC input 568 of digital-to-analog converter 560 and not based on loop filter input 567 of loop filter circuit 130 (FIG. 5).

Although FIG. 11 discloses a particular number of operations related to method 1100, method 1100 may be executed with greater or fewer operations than those depicted in FIG. 11. For example, after block 1115, method 1100 may continue with additional operations illustrated in FIG. 12. In addition, although FIG. 11 discloses a certain order of operations to be taken with respect to method 1100, the operations comprising method 1100 may be completed in any suitable order.

FIG. 12 illustrates a flow chart of an example method 1200 for using pulse-width modulation to generate a feedback clock in a phased lock loop. According to one example, method 1200 may begin at block 1210. Teachings of the present disclosure may be implemented in a variety of configurations of CIP PLL device 100. As such, the initialization point for method 1200 and the order of 1210-1215 comprising method 1200 may depend on the implementation chosen.

According to an example, block 1210 may be the same as blocks 910-945 in FIG. 9, blocks 1010-1015 in FIG. 10, and blocks 1110-1115 in FIG. 11. At block 1215, in response to a feedback capacitor coupled to the DAC output of the digital-to-analog converter being charged to a control voltage corresponding to the period setting and the duty cycle setting of the pulse-width modulation circuit, the DAC output of the digital-to-analog converter may be disabled so that the phase or frequency of the voltage controlled oscillator is no longer adjusted based on the DAC output of the digital-to-analog converter, and the phase or frequency of the voltage controlled oscillator may be adjusted based on the loop filter output of the loop filter circuit. In an example, in response to feedback capacitor 561 being charged to a control voltage corresponding to period setting in period register 152 and duty cycle setting in duty cycle register 153 of pulse-width modulation circuit 150, DAC input 568 of digital-to-analog converter 560 may be disabled so that the phase or frequency of voltage controlled oscillator circuit 140 is no longer adjusted based on DAC input 568, and the phase or frequency of voltage controlled oscillator circuit 140 may be adjusted based on loop filter input 567 of loop filter circuit 130 (FIG. 5).

Although FIG. 12 discloses a particular number of operations related to method 1200, method 1200 may be executed with greater or fewer operations than those depicted in FIG. 12. In addition, although FIG. 11 discloses a certain order of operations to be taken with respect to method 1200, the operations comprising method 1200 may be completed in any suitable order.

Methods 900-1200 may be implemented using CIP PLL device 100 or any other system operable to implement methods 900-1200. Although examples have been described above, other variations and examples may be made from this disclosure without departing from the spirit and scope of these disclosed examples.

1. A system comprising:
a reference divider circuit to divide a reference clock, the reference divider circuit comprising a reference divider output;
a phase-frequency detector circuit to detect a detected phase difference and a detected frequency difference based on the reference divider output and a feedback clock, the phase-frequency detector circuit comprising a divided reference clock input coupled to the reference divider output, a feedback clock input coupled to the feedback clock, and a detector output based on the detected phase and the detected frequency difference;
a loop filter circuit to filter the detector output, the loop filter circuit comprising a loop filter output;
a voltage controlled oscillator (VCO) circuit to generate a VCO clock output, the voltage controlled oscillator circuit comprising a VCO input coupled to the loop filter output, the VCO input to adjust at least one of a frequency and a phase of the VCO clock output;
a divider circuit to divide the VCO clock output, the divider circuit comprising a divider clock input coupled to the VCO clock output, a divider control input, and a divider clock output;
a pulse-width modulation (PWM) circuit, the pulse-width modulation circuit comprising:
a PWM clock input coupled to the divider clock output;
a period register to store a period value;
a duty cycle register to store a duty cycle value;
a pulse-width modulated output based on the period value and the duty cycle value, the pulse-width modulated output coupled to the divider control input; and
a counter rollover output to generate the feedback clock.

2. The system of claim 1, wherein:
the reference divider circuit, the phase-frequency detector circuit, the loop filter circuit, and the pulse-width modulation circuit are implemented in one or more peripherals of a microcontroller; and
the voltage controlled oscillator circuit and divider circuit are external to the microcontroller.

3. The system of claim 2, wherein the loop filter circuit comprises an operational amplifier.

4. The system of claim 2, wherein the phase-frequency detector circuit is implemented in one or more configurable logic cell peripherals of the microcontroller.

5. The system of claim 4, wherein the phase-frequency detector circuit and the loop filter circuit comprise:
a first D flip-flop comprising a first data input coupled to logic one, a first clock input coupled to the divided reference clock input, a first reset input, and a first output;
a second D flip-flop comprising a second data input coupled to logic one, a second clock input coupled to the feedback clock input, a second reset input, and a second output;
a NAND gate comprising a third input coupled to the first output, a fourth input coupled to the second output, and a third output coupled to the first reset input and the second reset input; and
an operational amplifier comprising an inverting input coupled to the first output and a feedback capacitor, a non-inverting input coupled to the second output, and a fourth output coupled to the loop filter output and the feedback capacitor.

6. The system of claim 2, wherein:
the microcontroller comprises a digital-to-analog converter (DAC) having a DAC output;
the loop filter circuit comprises a feedback capacitor coupled to the VCO input; and
the VCO input coupled to the loop filter output comprises the VCO input selectively coupled to the loop filter output and the DAC output.

7. The system of claim 6, wherein:
the VCO input configured to be coupled to the DAC output following a change of either the period register or the duty cycle register, and
the VCO input configured to be re-coupled to the loop filter output when the feedback capacitor is charged to a control voltage corresponding to the period value and the duty cycle value.

8. The system of claim 1, wherein:
the divider circuit comprises a dual modulus prescaler divider for dividing the VCO clock output by one of a first divisor and a second divisor;
the divider circuit divides the VCO clock output by the first divisor when the divider control input is high; and
the divider circuit divides the VCO clock output by the second divisor when the divider control input is low.

9. The system of claim 1, comprising:
a digital-to-analog converter (DAC) having a DAC output;
the loop filter circuit comprises a feedback capacitor coupled to the VCO input; and
the VCO input coupled to the loop filter output comprises the VCO input selectively coupled to the loop filter output and the DAC output,
the VCO input temporarily coupled to the DAC output following a change of either the period register or the duty cycle register, and
the VCO input re-coupled to the loop filter output when the feedback capacitor is charged to a control voltage corresponding to the period value and the duty cycle value.

10. An apparatus, comprising:
a reference divider circuit to divide a reference clock, the reference divider circuit comprising a reference divider output;
a phase-frequency detector circuit to detect a detected phase difference and a detected frequency difference based on the reference divider output and a feedback clock, the phase-frequency detector circuit comprising a divided reference clock input coupled to the reference divider output, a feedback clock input coupled to the feedback clock, and a detector output based on the detected phase difference and the detected frequency difference;
a loop filter circuit to filter the detector output, the loop filter circuit comprising a loop filter output;
a voltage controlled oscillator (VCO) control output pin coupled to the loop filter output, the VCO control output pin to adjust one of a frequency and a phase of a VCO clock output of an external voltage controlled oscillator circuit;
a VCO clock divider control output pin to select a divisor of an external clock divider circuit;
a divided VCO clock input pin for coupling to an output of the external clock divider circuit; and
a pulse-width modulation (PWM) circuit, the pulse-width modulation circuit comprising:
a PWM clock input coupled to the divided VCO clock input pin;
a period register to store a period value;
a duty cycle register to store a duty cycle value;
a pulse-width modulated output based on the period value and the duty cycle value, the pulse-width modulated output coupled to the VCO clock divider control output pin; and
a counter rollover output to generate the feedback clock.

11. The apparatus of claim 10, comprising one or more configurable logic cell peripherals to implement the phase-frequency detector circuit.

12. The apparatus of claim 11, wherein the phase-frequency detector circuit and the loop filter circuit comprise:
a first D flip-flop comprising a first data input coupled to logic one, a first clock input coupled to the divided reference clock input, a first reset input, and a first output;
a second D flip-flop comprising a second data input coupled to logic one, a second clock input coupled to the feedback clock input, a second reset input, and a second output;
a NAND gate comprising a third input coupled to the first output, a fourth input coupled to the second output, and a third output coupled to the first reset input and the second reset input; and
an operational amplifier comprising an inverting input coupled to the first output and a feedback capacitor, a non-inverting input coupled to the second output, and a fourth output coupled to the loop filter output and the feedback capacitor.

13. The apparatus of claim 10 comprising:
a digital-to-analog converter comprising a DAC output;
the loop filter circuit comprises a feedback capacitor coupled to the VCO control output pin; and
the VCO control output pin coupled to the loop filter output comprises the VCO control output pin selectively coupled to the loop filter output and the DAC output.

14. The apparatus of claim 13, wherein:
the VCO control output pin is configured to be coupled to the DAC output following a configuration change of the pulse-width modulation circuit, and
the VCO control output pin configured to be re-coupled to the loop filter output when the feedback capacitor is charged to a control voltage corresponding to the VCO clock output of the external voltage controlled oscillator circuit.

15. A system comprising:
the apparatus of claim 10;
the external clock divider circuit implemented as a dual modulus prescaler circuit external to the device, the dual modulus prescaler circuit comprising:
a prescaler output coupled to the divided VCO clock input pin of the device;
a prescaler control input coupled to the VCO clock divider control output pin of the device; and
a prescaler clock input; and
the external voltage controlled oscillator circuit is external to the device, the external voltage controlled oscillator circuit comprising:
an oscillator input coupled to the VCO control output pin of the device; and
an oscillator output coupled to the prescaler clock input.

16. A method comprising:
dividing a reference clock;
detecting a phase and frequency relationship between the divided reference clock and a feedback clock in a detector circuit;
filtering a detector output of the detector circuit in a loop filter circuit;
adjusting the phase or frequency of a voltage controlled oscillator based on a loop filter output of the loop filter circuit;
dividing an output oscillation signal of the voltage controlled oscillator in a dual modulus prescaler circuit;
clocking a pulse-width modulation circuit with a divided signal output of the dual modulus prescaler circuit;
selecting a divisor used by the dual modulus prescaler circuit based on an output signal of the pulse-width modulation circuit; and
generating the feedback clock based on a counter in the pulse-width modulation circuit.

17. The method of claim 16, wherein generating the feedback clock based on the counter in the pulse-width modulation circuit comprises generating the feedback clock based on the counter corresponding to a period setting in the pulse-width modulation circuit.

18. The method of claim 16, wherein detecting the phase and frequency relationship between the divided reference clock and the feedback clock in the detector circuit comprises a microcontroller configuring a configurable logic cell peripheral of the microcontroller to detect the phase and frequency relationship between the divided reference clock and the feedback clock in the detector circuit.

19. The method of claim 18, wherein:
the microcontroller comprises the loop filter circuit;
the loop filter circuit comprises an operational amplifier; and
filtering the detector output of the detector circuit in the loop filter circuit comprises using the operational amplifier to filter the detector output of the detector circuit.

20. The method of claim 16, comprising:
changing the frequency of the voltage controlled oscillator by changing one or more of a period setting in the pulse-width modulation circuit and a duty cycle setting in the pulse-width modulation circuit.

21. The method of claim 20, comprising:
corresponding to a change of one or more of the period setting and the duty cycle setting of the pulse-width modulation circuit, temporarily adjusting the phase or frequency of the voltage controlled oscillator based on a DAC output of a digital-to-analog converter and not based on the loop filter output of the loop filter circuit.

22. The method of claim 21, comprising:
in response to a feedback capacitor coupled to the DAC output of the digital-to-analog converter being charged to a control voltage corresponding to the period setting and the duty cycle setting of the pulse-width modulation circuit:
disabling the DAC output of the digital-to-analog converter so that the phase or frequency of the voltage controlled oscillator is no longer adjusted based on the DAC output of the digital-to-analog converter, and
adjusting the phase or frequency of the voltage controlled oscillator based on the loop filter output of the loop filter circuit.
